(19) United States
(12) Patent Application Publication
(10) Pub. No.: US 2025/0338478 A1
(43) Pub. Date: Oct. 30, 2025

(54) SEMICONDUCTOR DEVICE AND MANUFACTURING METHOD THEREOF, AND MEMORY SYSTEM

(71) Applicant: YANGTZE MEMORY TECHNOLOGIES CO., LTD., Wuhan (CN)

(72) Inventors: Yuhuan Zheng, Wuhan (CN); Yonggang Yang, Wuhan (CN)

(21) Appl. No.: 18/759,213

(22) Filed: Jun. 28, 2024

(30) Foreign Application Priority Data
Apr. 25, 2024 (CN) 202410511498.1

(51) Int. Cl. H10B 12/00

(52) U.S. Cl. CPC H10B 12/315; H10B 12/0335

(57) ABSTRACT

According to one aspect of the present disclosure, a semiconductor device is provided. The semiconductor device may include a first semiconductor structure. The first semiconductor structure may include a memory cell array comprising a plurality of memory cells arranged in an array along a first lateral direction and a second lateral direction. Each memory cell may include a vertical transistor and a storage element coupled to one end of the vertical transistor. The first semiconductor structure may include a plurality of contact structures. The contact structure may be located between the vertical transistor and the storage element. In two contact structures adjacent to a first contact structure among the plurality of contact structures along the first lateral direction, distances between any one of the two contact structures and the first contact structure may be the same.

### CROSS-REFERENCE TO RELATED APPLICATIONS

The present application claims the benefit of priority to Chinese Application No. 202410511498.1, filed on Apr. 25, 2024, which is hereby incorporated by reference in its entirety.

### TECHNICAL FIELD

The present disclosure relates to the technical field of semiconductors, and particularly to a semiconductor device and a manufacturing method thereof, and a memory system.

### BACKGROUND

The semiconductor device such as a dynamic random-access memory (DRAM) is one of the most important access components in an electronic system, and generally employs one transistor and one capacitor to constitute a 1T1C structure as a memory cell. Such 1T1C structure makes the dynamic random-access memory have a high integration degree and a low cost, and have an irreplaceable position in the computer access device. With the rapid development of semiconductor technology, the dynamic random-access memory is rapidly developing towards high density and high quality.

### SUMMARY

According to one aspect of the present disclosure, a semiconductor device is provided. The semiconductor device may include a first semiconductor structure. The first semiconductor structure may include a memory cell array comprising a plurality of memory cells arranged in an array along a first lateral direction and a second lateral direction. Each memory cell may include a vertical transistor and a storage element coupled to one end of the vertical transistor. The first semiconductor structure may include a plurality of contact structures. The contact structure may be located between the vertical transistor and the storage element. In two contact structures adjacent to a first contact structure among the plurality of contact structures along the first lateral direction, distances between any one of the two contact structures and the first contact structure may be the same.

In some implementations, the vertical transistor may include a semiconductor body extending along a vertical direction, and a gate structure in contact with at least a portion of a side surface of the semiconductor body. In some implementations, the gate structure may extend along the second lateral direction. In some implementations, a distance between adjacent semiconductor bodies may be greater than or equal to a distance between the adjacent contact structures.

In some implementations, sidewalls of the contact structure and the semiconductor body along the first lateral direction may be aligned in the vertical direction, and a distance between the other sidewalls of the adjacent semiconductor bodies along the first lateral direction may be greater than a distance between the other sidewalls of the adjacent contact structures along the first lateral direction.

In some implementations, a size of the contact structure along the first lateral direction may be greater than a size of the semiconductor body along the first lateral direction.

In some implementations, the first semiconductor structure may further include a plurality of bit lines. In some implementations, the bit line may extend along the first lateral direction and may be coupled to the other end of the vertical transistor. In some implementations, the first semiconductor structure may further include a plurality of isolation structures. In some implementations, the isolation structure may be located between adjacent vertical transistor groups along the second lateral direction and extends along the second lateral direction.

In some implementations, the plurality of isolation structures may include first isolation structures and second isolation structures alternately arranged along the first lateral direction. In some implementations, the first isolation structure may include at least one of a first dielectric layer or a first air gap, and the second isolation structure may include a second air gap.

In some implementations, the semiconductor device may further include a plurality of third air gaps. In some implementations, the third air gap may be located between adjacent bit lines and extends along the first lateral direction.

In some implementations, the first air gap, the second air gap, and the third air gap may communicate with each other.

In some implementations, the gate structure may include a gate electrode and a gate dielectric between the gate electrode and the semiconductor body in the first lateral direction and the second lateral direction.

In some implementations, the vertical transistor may further include a source and a drain respectively disposed on two ends of the semiconductor body in the vertical direction. In some implementations, one of the source and the drain of the vertical transistor may be coupled to the storage element in a respective memory cell, and the other one of the source and the drain of the vertical transistor may be coupled to a respective bit line.

In some implementations, the contact structure may include a first conductive layer and a second conductive layer. In some implementations, the first conductive layer may include a metal semiconductor compound, and the second conductive layer may include a metal.

In some implementations, the vertical transistor may include at least one of a gate-all-around (GAA) transistor, a tri-gate transistor, a double-gate transistor, or a single-gate transistor.

In some implementations, the storage element may include at least one of a capacitor, a ferroelectric capacitor, or a phase change memory (PCM) element.

In some implementations, the storage element may be a capacitor comprising a first electrode, a second electrode, and a capacitor dielectric.

In some implementations, the semiconductor device may further include a second semiconductor structure. In some implementations, the first semiconductor structure may be stacked with the second semiconductor structure along a vertical direction, and the second semiconductor structure may include a peripheral circuit.

In some implementations, the first semiconductor structure and the second semiconductor structure may be formed on a same substrate. In some implementations, the first semiconductor structure and the second semiconductor structure may be formed on different substrates.

According to another aspect of the present disclosure, a method of manufacturing a semiconductor device is provided. The method may include forming a first semiconductor structure. The forming the first semiconductor structure may include forming a memory cell array. The memory cell array may include a plurality of memory cells arranged in an array along a first lateral direction and a second lateral direction. Each memory cell may include a vertical transistor and a storage element coupled to one end of the vertical transistor. The forming the first semiconductor structure may include forming a plurality of contact structures. The contact structure may be located between the vertical transistor and the storage element, and in two contact structures adjacent to a first contact structure among the plurality of contact structures along the first lateral direction, distances between any one of the two contact structures and the first contact structure may be the same.

In some implementations, the forming the first semiconductor structure may include etching a semiconductor substrate through a mask stacking layer to form a semiconductor pillar array. In some implementations, the semiconductor pillar array may include semiconductor pillar rows arranged along the second lateral direction, and the semiconductor pillar rows may be separated by first spacing trenches. In some implementations, the mask stacking layer may include a first mask layer and a second mask layer. In some implementations, the forming the first semiconductor structure may include etching the semiconductor pillars through openings formed after removing the first mask layer to form a plurality of second spacing trenches extending along the second lateral direction. In some implementations, the plurality of second spacing trenches may separate each semiconductor pillar in the corresponding semiconductor pillar row into two semiconductor bodies.

In some implementations, the forming the plurality of contact structures may include recessing the second mask layer such that the recessed second mask layers are arranged at equal spacing along the first lateral direction. In some implementations, the forming the plurality of contact structures may include removing the recessed second mask layers to form first contact holes. In some implementations, the forming the plurality of contact structures may include enlarging the first contact holes to form second contact holes, wherein the second contact hole exposes at least an entire upper surface of the semiconductor body. In some implementations, the forming the plurality of contact structures may include forming the contact structures in the second contact holes.

In some implementations, the etching the semiconductor pillars through the openings formed after removing the first mask layer may include pulling back the first mask layer along the first spacing trench such that an opening of the first spacing trench that is located in the first mask layer is enlarged. In some implementations, the etching the semiconductor pillars through the openings formed after removing the first mask layer may include performing a deposition to form a first sacrificial layer filling the first spacing trench. In some implementations, the etching the semiconductor pillars through the openings formed after removing the first mask layer may include removing the first mask layer to form an opening in the first sacrificial layer, and etching the semiconductor pillar through the opening.

In some implementations, before removing the recessed second mask layers to form the first contact holes, the forming the first semiconductor structure further may include forming a second sacrificial layer and a second dielectric layer in the second spacing trench.

In some implementations, the forming the first semiconductor structure may further include removing the first sacrificial layer to form a third spacing trench. In some implementations, the forming the first semiconductor structure may further include forming a word line structure in the third spacing trench. In some implementations, the forming the first semiconductor structure may further include forming a second trench in the word line structure. In some implementations, the forming the first semiconductor structure may further include forming a first isolation structure in the second trench, wherein the word line structure is divided into two word lines through the first isolation structure.

In some implementations, the forming the contact structure in the second contact hole may include forming a first doped layer at a bottom of the second contact hole, wherein the first doped layer is in contact with the upper surface of the semiconductor body.

In some implementations, the forming the contact structure in the second contact hole further may include forming a first conductive layer on the first doped layer. In some implementations, the forming the contact structure in the second contact hole may further include forming a second conductive layer on the first conductive layer. In some implementations, the first conductive layer may include a metal semiconductor compound, and the second conductive layer comprises a metal.

In some implementations, the forming the memory cell array may include forming a capacitor coupled to the contact structure, wherein the capacitor is coupled to the semiconductor body through the contact structure.

In some implementations, the forming the first semiconductor structure may further include forming a second doped layer at another end opposite to the upper surface of the semiconductor body. In some implementations, the forming the first semiconductor structure may further include forming a bit line coupled with the second doped layer, wherein the bit line extends along the first lateral direction.

In some implementations, before the forming the second doped layer at another end opposite to the upper surface of the semiconductor body, the forming the first semiconductor structure further may include removing a second sacrificial layer in the second spacing trench to form a second air gap.

In some implementations, the forming the first semiconductor structure may further include forming a plurality of third air gaps located between adjacent bit lines. In some implementations, the third air gap extends along the first lateral direction.

According to a further aspect of the present disclosure, a memory system is provided. The memory system may include a semiconductor device including a first semiconductor structure. The first semiconductor structure may include a memory cell array comprising a plurality of memory cells arranged in an array along a first lateral direction and a second lateral direction. A memory cell may include a vertical transistor and a storage element coupled to one end of the vertical transistor. The first semiconductor structure may include a plurality of contact structures. The contact structure may be located between the vertical transistor and the storage element. In two contact structures adjacent to a first contact structure among the plurality of contact structures along the first lateral direction, distances between any one of the two contact structures and the first contact structure may be the same. The memory system may further include a memory controller configured to control the semiconductor device.

In some implementations, the vertical transistor may include a semiconductor body extending along a vertical direction, and a gate structure in contact with at least a portion of a side surface of the semiconductor body. In some implementations, the gate structure may extend along the second lateral direction. In some implementations, a distance between adjacent semiconductor bodies may be greater than or equal to a distance between the adjacent contact structures.

In some implementations, sidewalls of the contact structure and a semiconductor body along the first lateral direction may be aligned in a vertical direction, and a distance between the other sidewalls of adjacent semiconductor bodies along the first lateral direction may be greater than a distance between the other sidewalls of the adjacent contact structures along the first lateral direction.

In some implementations, a size of the contact structure along the first lateral direction may be greater than a size of the semiconductor body along the first lateral direction.

### BRIEF DESCRIPTION OF THE DRAWINGS

FIG. 1 is a schematic structural diagram I of a semiconductor device provided by an example of the present disclosure;

FIG. 2 is a flow chart of a manufacturing method of a semiconductor device provided by an example of the present disclosure;

FIG. 3a to FIG. 3s are schematic cross-sectional views of a process of forming a semiconductor body provided by an example of the present disclosure;

FIG. 4a to FIG. 4k are schematic cross-sectional views of a process of forming a first isolation structure and a contact structure provided by an example of the present disclosure; and

FIG. 5 is a schematic structural diagram II of a semiconductor device provided by an example of the present disclosure.

### DETAILED DESCRIPTION

The technical solutions in implementations of the present disclosure will be described below clearly and completely in conjunction with the implementations and the drawings of the present disclosure. Apparently, the implementations described are only part, but not all, of the implementations of the present disclosure. All other implementations obtained by those of ordinary skills in the art based on the implementations in the present disclosure without creative work shall fall within the scope of protection of the present disclosure.

In the following descriptions, a lot of details are given in order to provide the more thorough understanding of the present disclosure. However, it is apparent to those skilled in the art that the present disclosure may be implemented without one or more of these details. In other examples, in order to avoid confusion with the present disclosure, some technical features well-known in the field are not described. That is, not all the features of the actual examples are described here, and well-known functions and structures are not described in detail.

In the drawings, the sizes of a layer, a region, and an element and their relative sizes may be exaggerated for clarity. Like reference numerals denote like elements throughout the specification.

It is to be understood that when an element or a layer is referred to as being “on”, “adjacent to”, “connected to”, or “coupled to” other elements or layers, it may be directly on, adjacent to, connected to, or coupled to the other elements or layers, or intervening elements or layers may be present. In contrast, when an element is referred to as being “directly on”, “immediately adjacent to”, “directly connected to”, or “directly coupled to” other elements or layers, no intervening elements or layers are present. It is to be understood that, although terms first, second, third and the like may be used to describe various elements, components, regions, layers and/or parts, these elements, components, regions, layers and/or parts should not be limited by these terms. These terms are only used to distinguish one element, component, region, layer or part from another element, component, region, layer or part. Thus, a first element, component, region, layer or part discussed below may be represented as a second element, component, region, layer or part, without departing from the teachings of the present disclosure. However, when the second element, component, region, layer or part is discussed, it does not mean that the first element, component, region, layer or part is necessarily present in the present disclosure.

The spatially relative terms, such as “beneath”, “below”, “lower”, “under”, “over”, “upper”, etc., may be used here for ease of description to describe the relationship between one element or feature and other elements or features as illustrated in the figures. It is to be understood that the spatially relative terms are intended to further encompass different orientations of a device in use or operation in addition to the orientation depicted in the figures. For example, if the device in the drawings is flipped, then the elements or the features described as “below” or “under” or “beneath” other elements may be oriented “on” the other elements or features. Thus, the example terms “below” and “beneath” may comprise both upper and lower orientations. The device may be orientated otherwise (rotated by 90 degrees or other orientations), and the spatially descriptive words used here are interpreted accordingly.

The terms used here are only intended to describe the specific examples, and are not used as limitations to the present disclosure. As used here, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more other features, integers, steps, operations, elements, components, and/or groups. As used here, a term “and/or” comprises any and all combinations of related items listed.

In order to understand the present disclosure thoroughly, detailed operations and detailed structures will be proposed in the following description to set forth the technical solution of the present disclosure. The detailed descriptions of the preferred examples of the present disclosure are as follows. However, the present disclosure may also have other implementations in addition to these detailed descriptions.

With the development of dynamic random access memory technology, a size of a memory cell becomes smaller and smaller, and its array architecture changes from 8F² to 6F² then to 4F². Furthermore, based on requirements for ions and leakage current in a dynamic random access memory, an architecture of the memory changes from a planar array transistor to a recess gate array transistor, from the recess gate array transistor to a buried channel array transistor, and then from the buried channel array transistor to a vertical channel array transistor.

In some examples of the present disclosure, regardless of the planar transistor or the buried transistor, the dynamic random-access memory is composed of a plurality of memory cells. Each memory cell is composed of one transistor and one capacitor controlled by the transistor, e.g., the dynamic random access memory includes the architecture of 1 transistor (T) and 1 capacitor (C) (1T1C); and a main action principle of the memory cell is to utilize the number of charges stored in the capacitor to represent whether one binary bit is 1 or 0.

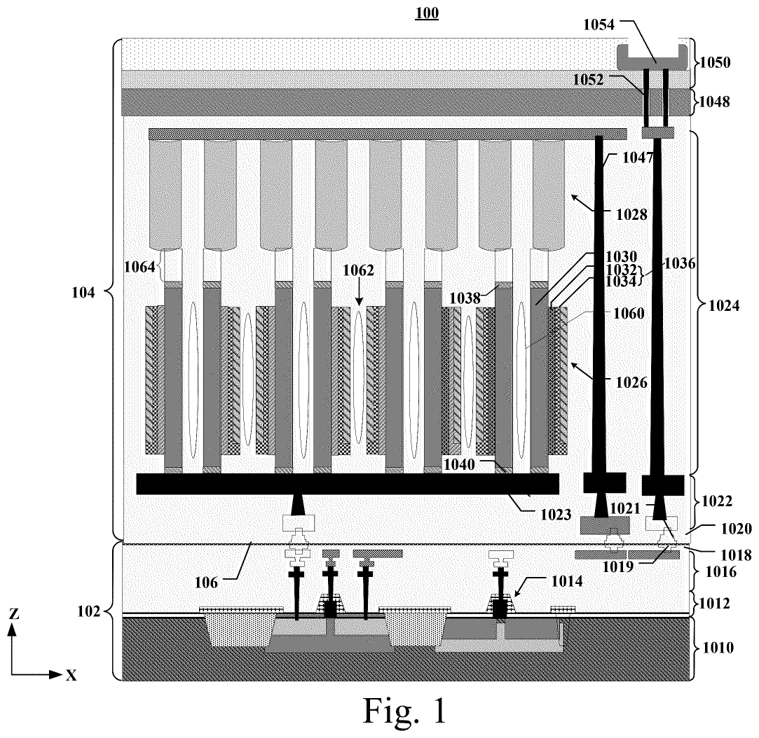

One of the architectures of the dynamic random-access memory is described in detail below in conjunction with FIG. 1. Before the semiconductor device shown in FIG. 1 is introduced, various directions that may be used in descriptions below are first defined. An extending direction of a semiconductor body is defined as a vertical direction (e.g., a Z-axis direction). A first lateral direction (e.g., an X-axis direction) and a second lateral direction (e.g., a Y-axis direction) intersecting with each other are defined in a plane perpendicular to the Z-axis direction. In some examples, the X-axis direction, the Y-axis direction, and the Z-axis direction may be perpendicular to each other.

FIG. 1 is a cross-sectional view of a semiconductor device 100 including a vertical transistor provided in an example of the present disclosure. As shown in FIG. 1, the semiconductor device 100 includes a second semiconductor structure 102 and a first semiconductor structure 104 stacked over the second semiconductor structure 102 along the Z-axis direction, where the second semiconductor structure 102 and the first semiconductor structure 104 are connected through a bonding interface 106; and the second semiconductor structure 102 and the first semiconductor structure 104 may be connected by means of hybrid bonding, etc. In some examples, the first semiconductor structure 104 may be bonded on a top of the second semiconductor structure 102 at the bonding interface 106 in a face-to-face manner. The second semiconductor structure 102 may include a first substrate 1010, a peripheral circuit 1012 located on a side of the first substrate 1010, and a first interconnect layer 1016 located on a side of the peripheral circuit 1012 that is away from the first substrate 1010, where the first interconnect layer 1016 is configured to transmit electrical signals of the peripheral circuit 1012. The peripheral circuit 1012 may include a plurality of transistors 1014. In some examples, trench isolation (e.g., shallow trench isolation (STI)) and doped regions (e.g., a well, source, and drain of the transistor 1014) may also be formed on the first substrate 1010 or in the first substrate 1010.

The second semiconductor structure 102 may further include a first bonding layer 1018 that is at the bonding interface 106 and located on a side of the first interconnect layer 1016 that is away from the peripheral circuit 1012. The first bonding layer 1018 may include a plurality of first bonding contacts 1019, and dielectric for electrically isolating the first bonding contacts 1019. The first bonding contacts 1019 and the surrounding dielectric in the first bonding layer 1018 may be used for hybrid bonding. Correspondingly, the first semiconductor structure 104 may also include a second bonding layer 1020 that is at the bonding interface 106 and located on a side of the first bonding layer 1018 that is away from the first interconnect layer 1016. The second bonding layer 1020 may include a plurality of second bonding contacts 1021, and dielectric for electrically isolating the second bonding contacts 1021. The second bonding contacts 1021 and the surrounding dielectric in the second bonding layer 1020 may be used for hybrid bonding. Here, the second bonding contacts 1021 are in contact with the first bonding contacts 1019 at the bonding interface 106.

In some examples, the peripheral circuit 1012 may further include a word line (WL) and a word line driver/row decoder, which are coupled to a second interconnect layer 1022 through the second bonding contacts 1021 in the second bonding layer 1020, the first bonding contacts 1019 in the first bonding layer 1018, and the first interconnect layer 1016. In some other examples, the peripheral circuit 1012 may further include a bit line (BL) 1023 and a bit line driver/column decoder, which are coupled to the second interconnect layer 1022 through the second bonding contacts 1021 in the second bonding layer 1020, the first bonding contacts 1019 in the first bonding layer 1018, and the first interconnect layer 1016. Here, the second interconnect layer 1022 includes a bit line 1023 above the second bonding layer 1020, and the bit line 1023 is configured to transmit electrical signals. In some other examples, the second semiconductor structure 102 and the first semiconductor structure 104 arranged in a stacking manner may not be connected by means of bonding, but are integrated on a same substrate (there is only the first substrate, no second substrate), so as to achieve a connection directly through one or more interconnect layers between the second semiconductor structure 102 and the first semiconductor structure 104. In this case, the first bonding layer 1018 and the first bonding contacts 1019 are not present in the second semiconductor structure 102, the second bonding layer 1020 and the second bonding contacts 1021 are not present in the first semiconductor structure 104, and the bonding interface 106 between the second semiconductor structure 102 and the first semiconductor structure 104 is also not present.

Referring to FIG. 1, the first semiconductor structure 104 further includes a memory cell array located on the second interconnect layer 1022, the memory cell array may include a plurality of memory cells 1024 arranged in an array along the X-axis direction and the Y-axis direction, a second substrate 1048 located on the memory cells 1024, and a pad-out third interconnect layer 1050 located on the second substrate 1048. A cross section of the semiconductor device 100 in FIG. 1 may be taken along a bit line direction (X-axis direction), and one bit line 1023 in the second interconnect layer 1022 laterally extending in the X-axis direction may be coupled to a column of memory cells 1024.

Here, each memory cell 1024 may include a vertical transistor 1026 and a capacitor structure 1028 coupled to the vertical transistor 1026, the vertical transistor 1026 includes a semiconductor body 1030 extending vertically (in the Z-axis direction), and a gate structure 1036 in contact with at least a portion of a side face of the semiconductor body 1030 in the bit line direction (X-axis direction); in some other examples, the gate structure may also fully surround the semiconductor body, semi-surround the semiconductor body, be located on two opposite side surfaces of the semiconductor body, etc., and details are not described here again. Here, the gate structure 1036 includes a gate electrode 1034 and a gate dielectric 1032 located between the gate electrode 1034 and the semiconductor body 1030 in the bit line direction (X-axis direction). In some examples, the gate dielectric 1032 adjoins one side surface of the semiconductor body 1030, and the gate electrode 1034 adjoins the gate dielectric 1032.

In some examples, the semiconductor body 1030 has two ends (an upper end and a lower end) in the vertical direction (Z-axis direction), and one (the lower end shown in FIG. 1) of the two ends extends beyond the gate dielectric 1032 into an interlayer dielectric (ILD) layer in the vertical direction (Z-axis direction), and the other end (the upper end shown in FIG. 1) of the semiconductor body 1030 is flush with a respective end of the gate dielectric 1032. In some other examples, the two ends (the upper end and the lower end) of the semiconductor body 1030 respectively extend beyond the gate electrode 1034 into the ILD layer in the vertical direction (Z-axis direction). In other words, the semiconductor body 1030 may have a vertical size larger than a vertical size (e.g., a depth in the Z-axis direction) of the gate electrode 1034, and the upper end and lower end of the semiconductor body 1030 both are not flush with the respective ends of the gate electrode 1034. As such, a short circuit between the bit line 1023 and the word line/gate electrode 1034 or between the word line/gate electrode 1034 and the capacitor structure 1028 can be avoided.

The vertical transistor 1026 may further include a source 1038 and a drain 1040 respectively disposed on the two ends (the upper end and the lower end) of the semiconductor body 1030 in the vertical direction (Z-axis direction) (positions of the source and the drain may be interchangeable, here and hereinafter, for example, the upper end is taken as the source 1038, and the lower end is taken as the drain 1040). In some implementations, the source 1038 is coupled to the capacitor structure 1028, and the drain 1040 is coupled to the bit line 1023.

Since the gate electrode may be part of the word line or extend in a word line direction as the word line, the first semiconductor structure 104 of the semiconductor device 100 may also include a plurality of word lines respectively extending in the word line direction (Y-axis direction). Here, each word line 1034 may be coupled to a row of memory cells 1024.

The vertical transistor 1026 vertically extends through the word line 1034 and is in contact with the word line 1034, and the drain 1040 of the vertical transistor 1026 at the lower end is in contact with the bit line 1023. Therefore, due to the vertical arrangement of the vertical transistor 1026, the word line 1034 and the bit line 1023 may be disposed in different planes in the vertical direction, which simplifies the routing of the word line 1034 and the bit line 1023. Here, the vertical transistors 1026 may be arranged in a mirror symmetrical manner to increase the density of the memory cells 1024 in the bit line direction (X-axis direction). Two adjacent vertical transistors 1026 in the bit line direction are in mirror symmetry with each other relative to a second isolation structure 1060; that is to say, the first semiconductor structure 104 may include a plurality of second isolation structures 1060, each of which extends parallel with the word line 1034 in the word line direction (Y-axis direction), and is disposed between the semiconductor bodies 1030 of two adjacent rows of the vertical transistor 1026. In some implementations, the rows of the vertical transistor 1026 that are separated by the second isolation structure 1060 are in mirror symmetry with each other relative to the second isolation structure 1060. It is to be understood that the second isolation structure 1060 may include air gaps, each of which is laterally disposed between the adjacent semiconductor bodies 1030. The first semiconductor structure 104 further includes a plurality of first isolation structures 1062, each of which extends parallel with the word line 1034 (also referred to herein as “gate electrode 1034”) in the word line direction (Y-axis direction), and is disposed between the word lines 1034 of two adjacent rows of the vertical transistor 1026. It is to be understood that sizes of the first isolation structure 1062 and the word line 1034 in the bit line direction (X-axis direction) may be same as or different from a size of the second isolation structure 1060 in the bit line direction (X-axis direction), and when the sizes of the first isolation structure and the word line in the bit line direction (X-axis direction) are different from the size of the second isolation structure in the bit line direction (X-axis direction), spacings among a plurality of semiconductor bodies 1030 arranged in the bit line direction (X-axis direction) are different, e.g., the plurality of semiconductor bodies 1030 arranged in the bit line direction (X-axis direction) are non-uniformly arranged.

As shown in FIG. 1, the capacitor structure 1028 is located above the source 1038 (e.g., an upper end portion of the semiconductor body 1030) of the vertical transistor 1026 and is in contact with the source 1038, and the capacitor structure 1028 may be a vertical capacitor.

In some implementations, a contact structure 1064 is formed between the capacitor structure 1028 and the vertical transistor 1026 to reduce contact resistance. As shown in FIG. 1, the contact structure 1064 may include a first conductive layer and a second conductive layer successively arranged in a stacking manner from bottom to top, and the first conductive layer includes a metal semiconductor compound, and the second conductive layer includes a metal. As shown in FIG. 1, the first semiconductor structure 104 may further include a capacitor contact 1047 in contact with a common plate of a second electrode to couple the second electrode of the capacitor structure 1028 to the peripheral circuit 1012 or directly to ground. In some implementations, the ILD layer forming the capacitor structure 1028 has a dielectric material (e.g., silicon oxide) same as two ILD layers into which the semiconductor body 1030 extends. Configuration of the capacitor structure 1028 may include any suitable structure and configuration, such as a planar capacitor, a stacked capacitor, a multi-fin capacitor, a cylindrical capacitor, a trench capacitor, or a substrate-plate capacitor.

As shown in FIG. 1, the vertical transistor 1026 vertically extends through the word line 1034 and is in contact with the word line 1034, the drain 1040 of the vertical transistor 1026 at a lower end portion is in contact with the bit line 1023, and the source 1038 of the vertical transistor 1026 at the upper end is in contact with the capacitor structure 1028. That is, due to the vertical arrangement of the vertical transistor 1026, the bit line 1023 and the capacitor structure 1028 may be disposed in different planes in the vertical direction, and coupled to respective end portions of the vertical transistor 1026 of the memory cell 1024 in the vertical direction. In some implementations, the bit line 1023 and the capacitor structure 1028 are disposed on opposite side surfaces of the vertical transistor 1026 in the vertical direction, and compared with a conventional memory cell in which a bit line and a capacitor structure are disposed on a same side surface of a planar transistor, the routing of the bit line 1023 is simplified and coupling capacitance between the bit line 1023 and the capacitor structure 1028 is reduced.

In some examples, the vertical transistor 1026 is vertically disposed between the capacitor structure 1028 and the bonding interface 106. That is, the vertical transistor 1026 may be arranged to be closer to the peripheral circuit 1012 of the second semiconductor structure 102 and the bonding interface 106 than the capacitor structure 1028. Since the bit line 1023 and the capacitor structure 1028 are coupled to the opposite ends of the vertical transistor 1026, the bit line 1023 (as part of the second interconnect layer 1022) is vertically disposed between the vertical transistor 1026 and the bonding interface 106 to reduce an interconnection routing distance and complexity.

In some examples, the first semiconductor structure 104 further includes the second substrate 1048 disposed above the memory cell 1024, and a pad-out third interconnect layer 1050 above the memory cell 1024. The pad-out third interconnect layer 1050 may include interconnects (e.g., a contact pad 1054) in one or more ILD layers.

In some examples, the first semiconductor structure 104 further includes one or more contacts 1052, which extends through part of the pad-out third interconnect layer 1050 and the second substrate 1048 to couple the pad-out third interconnect layer 1050 to the memory cell 1024 and the second interconnect layer 1022. As such, the peripheral circuit 1012 may be coupled to the memory cell 1024 through the first interconnect layer 1016 and the second interconnect layer 1022 as well as the second bonding layer 1020 and the first bonding layer 1018, and the peripheral circuit 1012 and the memory cell 1024 may be coupled to an external circuit through the contact 1052 and the pad-out third interconnect layer 1050.

As described above, in order to reduce the contact resistance between the capacitor structure 1028 and the vertical transistor 1026, the contact structure 1064 is disposed between the capacitor structure 1028 and the vertical transistor 1026.

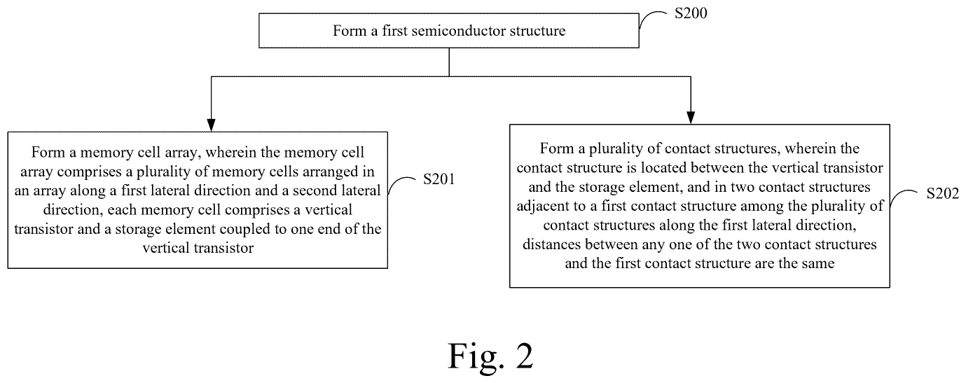

An example of the present disclosure provides a manufacturing method of a semiconductor device. FIG. 2 is a flow chart of a manufacturing method of a semiconductor device provided by an example of the present disclosure. The method may include operation S200: forming a first semiconductor structure.

Operation S200 may include operation S201: forming a memory cell array, where the memory cell array includes a plurality of memory cells arranged in an array along a first lateral direction and a second lateral direction, each memory cell includes a vertical transistor and a storage element coupled to one end of the vertical transistor.

Operation S200 may further include operation S202: forming a plurality of contact structures, where the contact structure is located between the vertical transistor and the storage element, and in two contact structures adjacent to a first contact structure among the plurality of contact structures along the first lateral direction, distances between any one of the two contact structures and the first contact structure are the same.

It is to be understood that the operations shown in FIG. 2 are not exclusive, and the other operations may be performed as well before, after, or between any of operations in the shown manufacturing method. A sequence of the operations shown in FIG. 2 may be adjusted according to actual requirements. It is to be noted that, a semiconductor device may include one contact structure, one semiconductor body, and one storage element, or a plurality of contact structures, a plurality of semiconductor bodies, and a plurality of storage elements, here and hereinafter, for example, the semiconductor device includes the plurality of contact structures, the plurality of semiconductor bodies, and the plurality of storage elements.

As described above, there may be a variety of different relative positions between the gate structure and the semiconductor body in the semiconductor device, and specific manufacturing methods corresponding to different relative positions are different. In the examples of the present disclosure, description is performed by using an example that two gate structures corresponding to two adjacent semiconductor bodies are disposed back-to-back, respectively (the back-to-back disposing is shown in FIG. 1). Based on this, the semiconductor device may include the plurality of contact structures, the plurality of semiconductor bodies, and the plurality of storage elements, which are arranged in an array along the X-axis direction and the Y-axis direction. However, it is to be understood that the following formation method of a semiconductor structure is used only to illustrate the present disclosure and is not intended to limit the scope of the present disclosure.

There are various methods of forming the contact structures and the semiconductor bodies, and several method are exemplarily shown in the examples of the present disclosure. A formation process of the plurality of contact structures and the plurality of semiconductor bodies is described below in detail in conjunction with the drawings.

In some examples, forming the first semiconductor structure includes: etching a semiconductor substrate through a mask stacking layer to form a semiconductor pillar array, where the semiconductor pillar array includes semiconductor pillar rows arranged along the second lateral direction. The mask stacking layer includes a first mask layer and a second mask layer. In some examples, forming the first semiconductor structure includes: etching the semiconductor pillars through openings formed after removing the first mask layer to form a plurality of second spacing trenches extending along the second lateral direction, where the plurality of second spacing trenches separate each semiconductor pillar in the corresponding semiconductor pillar row into two semiconductor bodies.

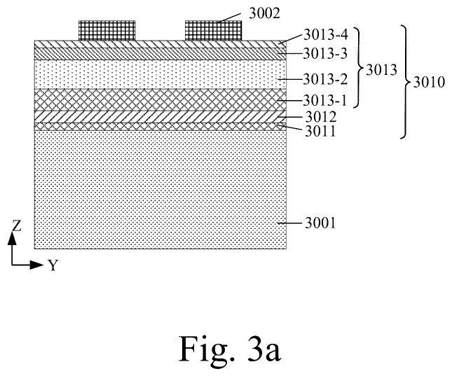

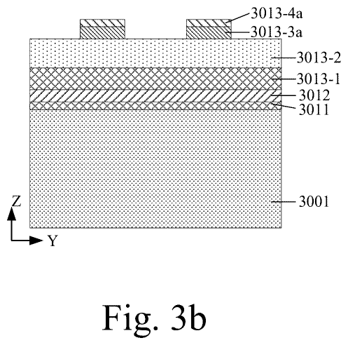

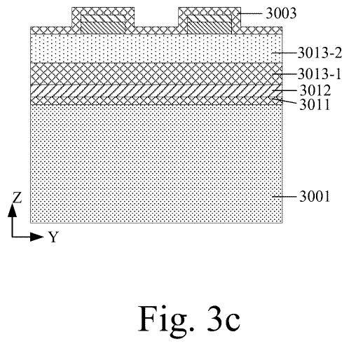

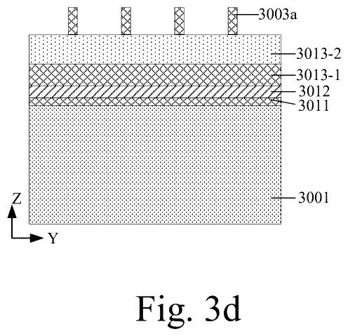

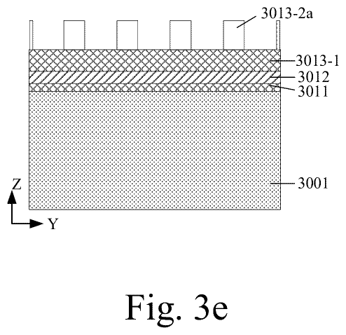

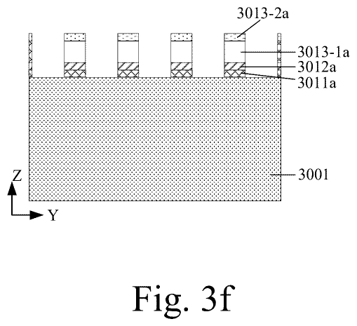

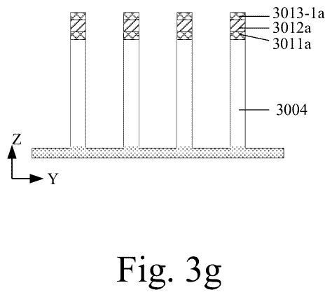

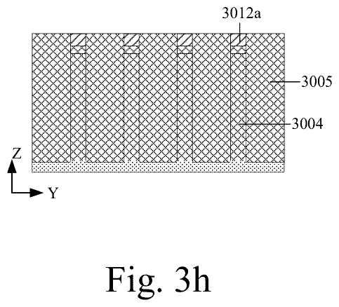

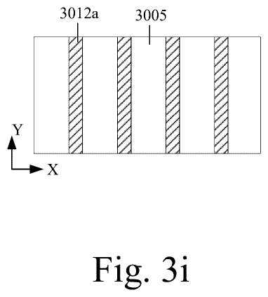

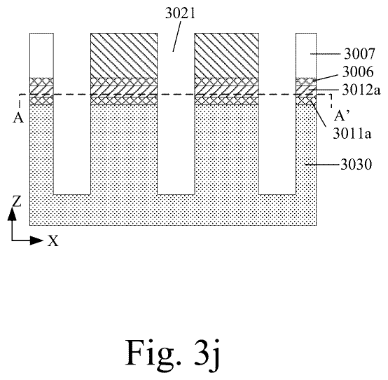

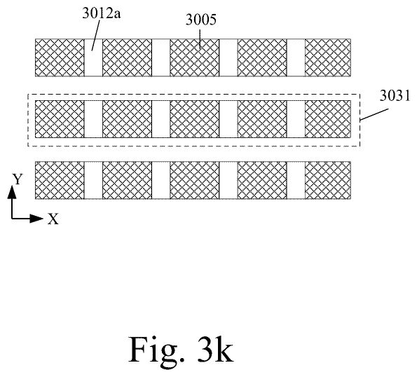

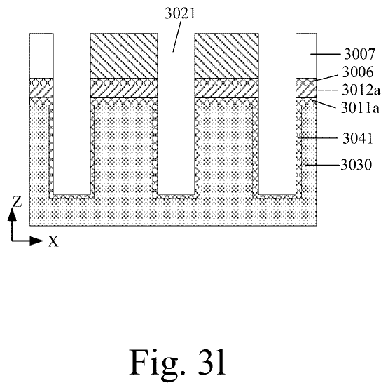

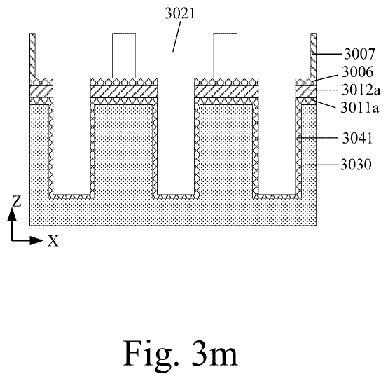

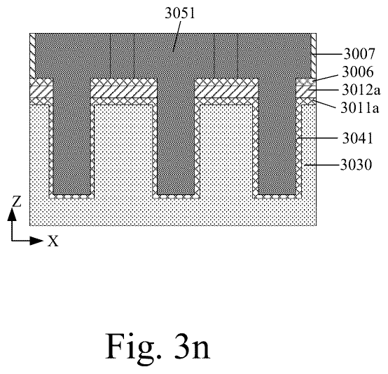

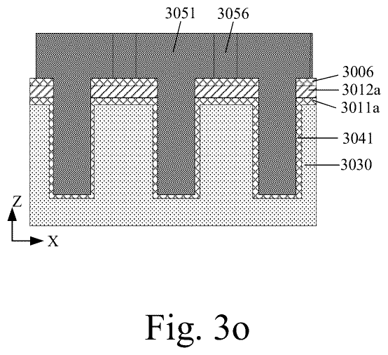

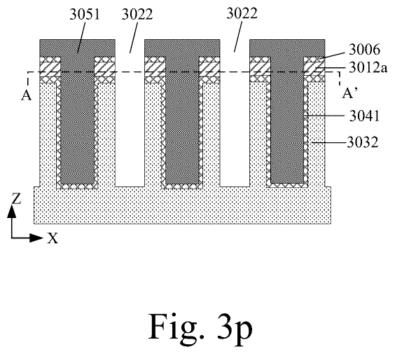

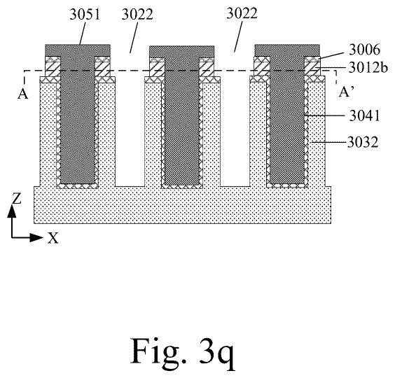

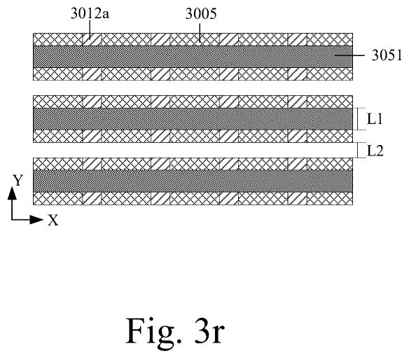

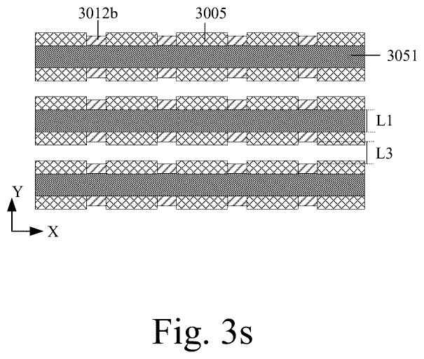

FIG. 3a to FIG. 3s are schematic cross-sectional views of a process of forming a semiconductor body provided by an example of the present disclosure. The process of forming the plurality of semiconductor bodies is described below in detail in conjunction with the drawings.

Referring to FIG. 3a, an initial stack layer 3010 and a patterned first photoresist layer 3002 are formed on a semiconductor substrate 3001. The initial stack layer 3010 includes a first oxide layer 3011, a second mask layer 3012, and a third mask layer 3013 successively arranged in a stacking manner from bottom to top. The first oxide layer 201 may be formed by an oxidation process of the semiconductor substrate 3001. A method of forming the second mask layer 3012 and the third mask layer 3013 includes, but is not limited to, processes such as physical-vapor deposition (PVD), chemical-vapor deposition (CVD), atomic-layer deposition (ALD), and the like.

In some examples, the third mask layer 3013 includes a second oxide layer 3013-1, a hard mask layer 3013-2, a core mold layer 3013-3, and an anti-reflection layer 3013-4, where a material of the second oxide layer may include silicon oxide, a material of the hard mask layer may include amorphous silicon (α-Si) or polysilicon (poly), a material of the core mold layer may include various types of carbon such as amorphous carbon (a-C), spin-on carbon (SOC), ashable hard-mask (AHM) carbon, transparent carbon (TC); and a material of the anti-reflection layer may include titanium nitride (TiN), silicon oxynitride (SiON), silicon carbide (SiC), aluminum oxide (AlO), or the like.

FIGS. 3b to 3g show a process of forming a semiconductor wall by utilizing self-aligned quadruple patterning (SAQP). Referring to FIG. 3b, the patterned first photoresist layer 3002 is utilized as a mask to etch the anti-reflection layer 3013-4 and the core mold layer 3013-3, patterns are transferred to the anti-reflection layer 3013-4 and the core mold layer 3013-3 to form an anti-reflection layer 3013-4a and a core mold layer 3013-3a, and the patterned photoresist layer 3002 is removed. Referring to FIG. 3c, a sidewall material layer 3003 is formed on the anti-reflection layer 3013-4a and the core mold layer 3013-3a. Referring to FIG. 3d, the sidewall material layer 3003 is selectively etched to remove the sidewall material layer parallel to a surface direction of the semiconductor substrate, while the sidewall material layer perpendicular to the surface direction of the semiconductor substrate is reserved, e.g., a sidewall 3003a is reserved. In some examples, an anisotropic blanket dry etch process may be employed to selectively etch the sidewall material layer 3003. Referring to FIG. 3e, the sidewall 3003a is taken as a mask to etch the hard mask layer 3013-2, a pattern is transferred to the hard mask layer 3013-2 to form a hard mask layer 3013-2a, and the sidewall 3003a is removed. Referring to FIG. 3f, the hard mask layer 3013-2a is taken as a mask to etch the first oxide layer 3011, the second mask layer 3012, and the second oxide layer 3013-1, patterns are transferred to the first oxide layer 3011, the second mask layer 3012, and the second oxide layer 3013-1 to form a first oxide layer 3011a, a second mask layer 3012a, and a second oxide layer 3013-1a. Referring to FIG. 3g, the hard mask layer 3013-2a, the first oxide layer 3011a, the second mask layer 3012a, and the second oxide layer 3013-1a are taken as masks to etch the semiconductor substrate 3001 to form semiconductor walls 3004, and the semiconductor walls 3004 are arranged at intervals along the Y-axis direction. It is to be noted that, since the material of the hard mask layer includes silicon, the hard mask layer 3013-2a is also removed when the semiconductor substrate is etched.

Referring to FIG. 3h, an insulation material is deposited and is filled between the semiconductor walls 3004. The excess insulation material and the first oxide layer 3011a are removed through a chemical-mechanical polishing (CMP) process, so as to expose the second mask layer 3012a.

Referring to FIG. 3i, the semiconductor walls 3004 are arranged at intervals along the X-axis direction, and extend along the Y-axis direction. An insulation layer 3005 formed by the insulation material is between the adjacent semiconductor walls 3004. It is to be noted that FIG. 3i is a top view of FIG. 3h. Thus, FIG. 3i only shows the arrangement and extending of the second mask layers 3012a. It can be understood that the arrangement and extending of the semiconductor walls 3004 are the same as those of the second mask layers 3012a.

Referring to FIG. 3j, patterned third oxide layer 3006 and first mask layer 3007 are formed on a structure shown in FIG. 3h and the patterned third oxide layer 3006 and first mask layer 3007 are taken as masks to etch the second mask layers 3012a and the semiconductor walls 3004 to form a plurality of first spacing trenches 3021 extending along the Y-axis direction, and the plurality of first spacing trenches 3021 separate a plurality of rows of the semiconductor walls 3004 into an array of semiconductor pillars 3030.

In some examples, the second mask layer and the first mask layer constitute a mask stacking layer.

It is to be noted that, FIGS. 3a to 3i are cross-sectional views along a ZOY plane, and cross-sectional views from FIG. 3j to subsequent cross-sectional views with respect to the manufacturing process are all cross-sectional views along a ZOX plane.

Referring to FIG. 3k, the array of the semiconductor pillars 3030 includes semiconductor pillar rows 3031 arranged along the Y-axis direction. FIG. 3k is a schematic cross-sectional view along an AA′ direction in FIG. 3j. Thus, FIG. 3k only shows the arrangement and extending of the second mask layers 3012a. It can be understood that the arrangement and extending of the semiconductor pillars 3030 are the same as those of the second mask layers 3012a.

Referring to FIG. 3l, sidewalls of the semiconductor pillars 3030 exposed from the first spacing trenches 3021 are oxidized through rapid-thermal oxidation (RTO) to form gate dielectric 3041.

In some examples, the etching the semiconductor pillar through the opening formed after removing the first mask layer includes: pulling back the first mask layer along the first spacing trench such that an opening of the first spacing trench that is located in the first mask layer is enlarged; performing a deposition to form a first sacrificial layer filling the first spacing trench; and removing the first mask layer to form an opening in the first sacrificial layer, and etching the semiconductor pillar through the opening.

Referring to FIG. 3m, the first mask layer 3007 is pulled back along the first spacing trench 3021 such that the opening of the first spacing trench 3021 that is located in the first mask layer 3007 is enlarged. In other words, a size of the first mask layer 3007 in the X-axis direction is reduced by pulling back the first mask layer 3007. In some examples, a method for pulling back the first mask layer 3007 may include, but is not limited to, dry etching.

Referring to FIG. 3n, a deposition is performed to form a first sacrificial layer 3051 filling the first spacing trench 3021. A material of the first sacrificial layer may include tungsten.

Referring to FIG. 3o, the first mask layer 3007 is removed to form openings 3056 in the first sacrificial layer 3051.

Referring to FIG. 3p, the semiconductor pillars 3030 are etched through the openings 3056 to form a plurality of second spacing trenches 3022 extending along the Y-axis direction, and the plurality of second spacing trenches 3022 separate each semiconductor pillar 3030 in the corresponding semiconductor pillar row into two semiconductor bodies 3032.

In some examples, forming the plurality of contact structures includes: recessing the second mask layer such that the recessed second mask layers are arranged at equal spacing along the first lateral direction; removing the recessed second mask layers to form first contact holes; enlarging the first contact holes to form second contact holes, where the second contact hole exposes at least an entire upper surface of the semiconductor body; and forming the contact structures in the second contact holes.

Referring to FIG. 3q, the first sacrificial layer 3051 and the second mask layer 3012a are recessed such that recessed second mask layers 3012b are arranged at equal spacing along the X-axis direction. It is to be noted that, when the first sacrificial layer 3051 and the second mask layer 3012a are recessed, the patterned third oxide layer 3006 is also recessed. In some examples, a method for recessing the first sacrificial layer 3051 and the second mask layer 3012a may include, but is not limited to, dry etching.

Referring to FIGS. 3r and 3s, FIG. 3r is a schematic cross-sectional view along an AA′ direction in FIG. 3p, and FIG. 3s is a schematic cross-sectional view along an AA′ direction in FIG. 3q. By comparing FIG. 3r with FIG. 3s, it can be seen that after the first sacrificial layer and the second mask layer are recessed, spacings between the adjacent recessed second mask layers 3012b along the X-axis direction are the same. In an example, referring to FIG. 3r, spacings between the adjacent second mask layers 3012a along the X-axis direction are unequal, e.g., L2 is not equal to L1. Referring to FIG. 3s, spacings between the adjacent recessed second mask layers 3012b along the X-axis direction are the same, e.g., L3 is equal to L1. The “equal spacing” described here refers to an ideal state in terms of a process requirement. Tt is to be understood that there are small deviations caused by manufacturing errors, etc., in an actual manufacturing process.

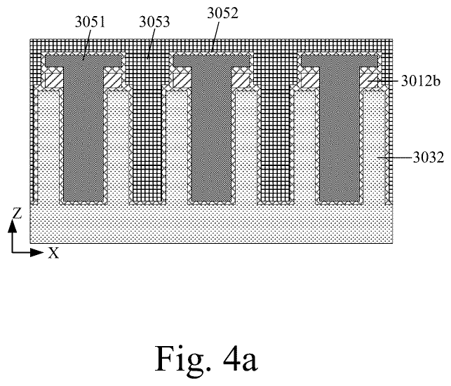

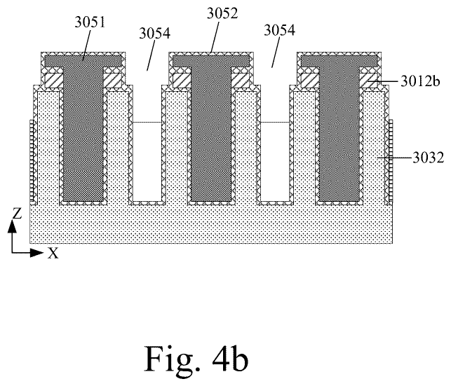

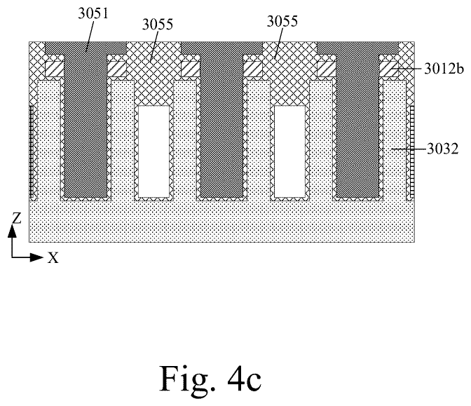

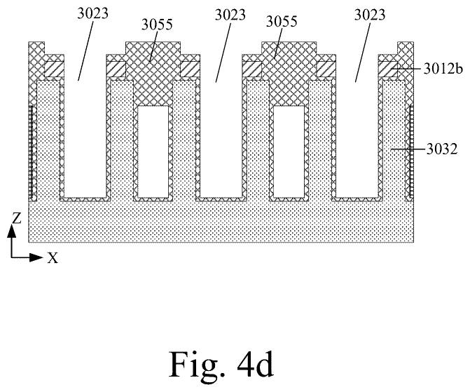

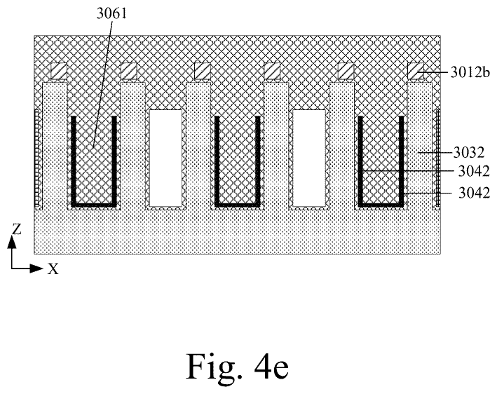

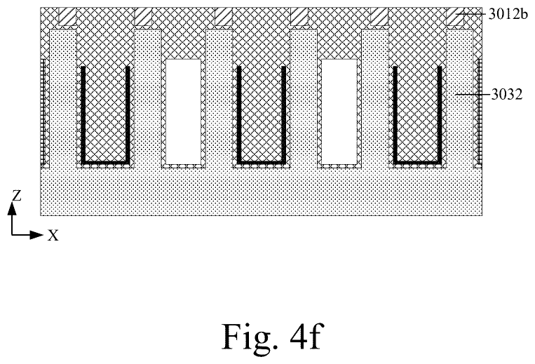

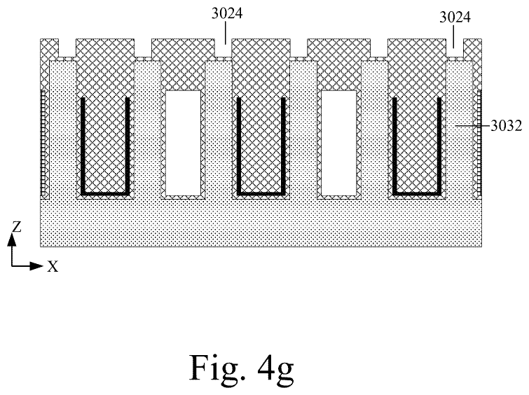

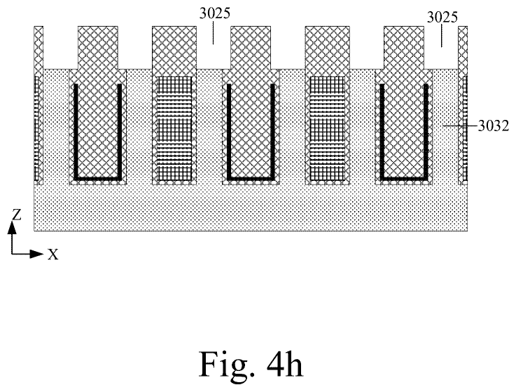

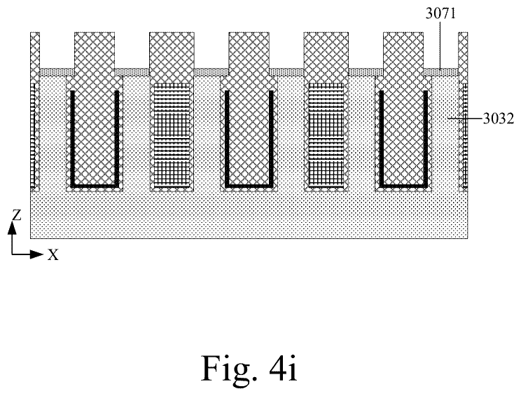

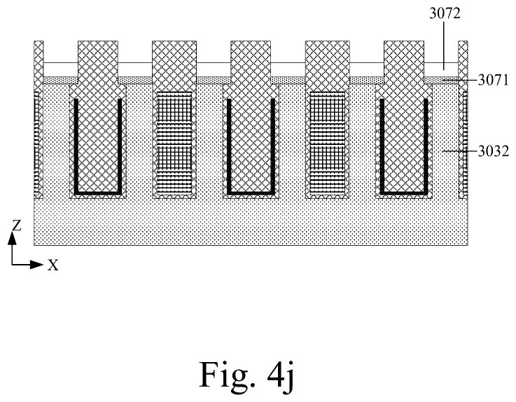

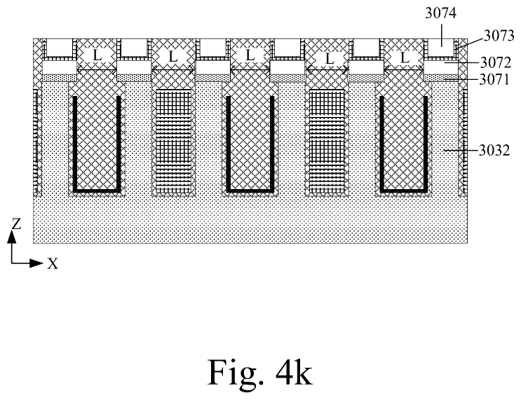

FIGS. 4a to 4e are schematic cross-sectional views of a process of forming a first isolation structure provided by an example of the present disclosure. The process of forming the first isolation structure is described below in detail in conjunction with the drawings. It is to be noted that, FIGS. 4a to 4k and FIGS. 3a to 3s are consecutive schematic cross-sectional views of the manufacturing method.

In some examples, before removing the recessed second mask layers to form the first contact holes, forming the first semiconductor structure further includes: forming a second sacrificial layer and a second dielectric layer in the second spacing trench.

In some examples, forming the first semiconductor structure further includes: removing the first sacrificial layer to form a third spacing trench; forming a word line structure in the third spacing trench; forming a second trench in the word line structure; and forming the first isolation structure in the second trench, where the word line structure is divided into two word lines through the first isolation structure.

Referring to FIG. 4a, a fourth oxide layer 3052 and a second sacrificial layer 3053 are formed through a deposition in the second spacing trench 3022. FIG. 4a shows a manufacturing process following FIG. 3s.

Referring to FIG. 4b, the second sacrificial layer 3053 is recessed to remove part of the second sacrificial layer, so as to form a groove 3054. In some examples, a method for recessing the second sacrificial layer 3053 may include, but is not limited to, dry etching.

Referring to FIG. 4c, a second dielectric layer material is deposited to form a second dielectric layer 3055 in the groove 3054.

It is to be noted that, in a process of actually depositing the second dielectric layer material, the second dielectric layer material covers an upper surface of the first sacrificial layer, and, after a deposition is completed, a CMP process may be employed to remove excess second dielectric layer material, so as to expose the upper surface of the first sacrificial layer 3051.

Referring to FIG. 4d, the first sacrificial layer 3051 is removed to form a third spacing trench 3023.

Referring to FIG. 4e, the word line structure is formed in the third spacing trench 3023, the second trench is formed in the word line structure, the first isolation structure 3061 is formed in the second trench, where the word line structure is divided into two word lines 3042 through the first isolation structure 3061. The first isolation structure 3061 shown in FIG. 4e may include a first isolation structure material between the two word lines 3042 and a first isolation structure material over the two word lines 3042. In an example, the first isolation structure material includes silicon oxide.

It is to be noted that, cross-sectional views from FIG. 3a to subsequent cross-sectional views with respect to the manufacturing process are all intermediate phases for manufacturing, some structural topographies shown in the figures may not be in final product form of the semiconductor device, for example, lower ends of the two word lines (gate electrodes) divided by the first isolation structure shown in the figures are connected together, lower ends of word lines (gate electrodes) in the final product of the semiconductor device are disconnected to form a back-to-back form (as shown in FIG. 1).

FIGS. 4f to 4k are schematic cross-sectional views of a process of forming a contact structure provided by an example of the present disclosure. The process of forming the first isolation structure is described below in detail in conjunction with the drawings.

In some examples, forming the plurality of contact structures includes: removing the recessed second mask layers to form first contact holes; enlarging the first contact holes to form second contact holes, where the second contact hole exposes at least an entire upper surface of the semiconductor body; and forming the contact structures in the second contact holes.

In some examples, forming the contact structure in the second contact hole further includes: forming a first doped layer at a bottom of the second contact hole, where the first doped layer is in contact with the upper surface of the semiconductor body.

In some examples, forming the contact structure in the second contact hole further includes: forming a first conductive layer on the first doped layer; and forming a second conductive layer on the first conductive layer, where the first conductive layer includes a metal semiconductor compound, and the second conductive layer includes a metal.

Referring to FIG. 4f, excess first isolation structure material is removed through the CMP process to expose the recessed second mask layer 3012b.

It is to be noted that, in the process of forming the first isolation structure in the second trench, the first isolation structure material covers an upper surface of the recessed second mask layer, and, after a deposition is completed, the CMP process is employed to remove excess first isolation structure material, so as to expose the upper surface of the recessed second mask layer.

Referring to FIG. 4g, the recessed second mask layers 3012b are removed to form first contact holes 3024.

Referring to FIG. 4h, the first contact holes 3024 are enlarged (CD enlarge) to form second contact holes 3025, and the second contact holes 3025 expose at least an entire upper surface of the semiconductor body 3032. The second contact holes 3025 are arranged at equal spacing along the X-axis direction. In some examples, a method for enlarging the first contact holes 3024 may include, but is not limited to, dry etching.

In some examples, while the first contact holes 3024 are enlarged, the top of the semiconductor body 3032 is also etched, resulting in a reduction in a size of the semiconductor body 3032 along the Z-axis direction.

Referring to FIG. 4i, a doped semiconductor material is deposited in the second contact hole 3025 and is recessed to form a first doped layer 3071, where the first doped layer 3071 is in contact with the upper surface of the semiconductor body 3032. The doped semiconductor material includes doped polysilicon, and may particularly include P-doped polysilicon.

Referring to FIG. 4j, a first conductive layer 3072 is formed on the first doped layer 3071. The first conductive layer 3072 includes a metal semiconductor compound, in some examples, metal elements in the metal semiconductor compound include, but are not limited to, nickel, cobalt, titanium, or the like. In some examples, the first conductive layer may be formed by metallizing a semiconductor layer. The semiconductor layer here may be the first doped layer, or may also be a semiconductor layer that is re-formed on the first doped layer.

It can be understood that, since the metal semiconductor compound may be formed by metallizing the semiconductor layer, the contact structure and the semiconductor body may be self-aligned.

Referring to FIG. 4k, a second conductive layer is formed on the first conductive layer 3072, and is located on a side of the first conductive layer that is away from the first doped layer. In some examples, the second conductive layer includes a first sub-layer 3073 and a second sub-layer 3074, where the first sub-layer 3073 encloses other surfaces of the second sub-layer 3074 other than an upper surface. The first sub-layer 3073 is in contact with the first conductive layer 3072. A material of the first sub-layer may include titanium nitride, and a material of the second sub-layer includes, but is not limited to, tungsten or copper.

In some examples, the first doped layer 3071, the first conductive layer 3072, the first sub-layer 3073, and the second sub-layer 3074 constitute the contact structure. The first doped layer 3071 in the contact structure is in contact with the semiconductor body, and the second sub-layer 3074 in the contact structure is in contact with a storage element.

As shown in FIG. 4k, all of distances between any two adjacent contact structures among the plurality of contact structures are L, e.g., the plurality of contact structures arranged along the X-axis direction are uniformly arranged at equal spacing.

In some examples, forming the memory cell array includes forming a capacitor coupled to the contact structure, where the capacitor is coupled to the semiconductor body through the contact structure.

In some examples, forming the capacitor coupled to the contact structure includes forming a cup-shaped capacitor CUP, a cylindrical capacitor CYL, or a pillar-shaped capacitor PIL. A shape of the capacitor may be selectively set according to actual requirements, and is not limited in the present disclosure.

In some examples, forming the first semiconductor structure further includes: forming a capacitor contact coupled to the capacitor. The capacitor contact is coupled to a second electrode of the capacitor structure, and is configured to couple the second electrode of the capacitor structure to a peripheral circuit or directly to ground.

In some examples, forming the first semiconductor structure further includes: thinning a back side of the semiconductor substrate to expose the gate dielectric and another end opposite to the upper surface of the semiconductor body. It is to be noted that, when the back side of the semiconductor substrate is thinned, the fourth oxide layer and the second sacrificial layer are also exposed.

In some examples, forming the first semiconductor structure further includes: removing the fourth oxide layer and the second sacrificial layer in the second spacing trench to form a second air gap. Here, the second air gap is used as a second isolation structure. The second doped layer is configured to form a drain.

In some examples, forming the first semiconductor structure further includes: forming a word line on at least one side of the semiconductor body.

In some examples, forming the word line on the at least one side of the semiconductor body includes: forming the word line located on one side surface of the semiconductor body; or forming the word line located on two opposite side surfaces of the semiconductor body; or forming the word line surrounding side surfaces of the semiconductor body.

It can be understood that the contact structure in the examples of the present disclosure may be applied to different word line (gate structure) scenarios. For example, the contact structure in the examples of the present disclosure may be applied to a scenario in which two word line structures corresponding to two adjacent semiconductor bodies are respectively disposed back-to-back, the back-to-back disposing scenario is employed as an example in various drawings in the examples of the present disclosure.

In some examples, forming the first semiconductor structure further includes: forming a third doped layer on an end corresponding to the upper surface of the semiconductor body. Here, the third doped layer is configured to form a source (positions of the source and the drain may be interchangeable, here, for example, an upper end of the semiconductor body is the source, and a lower end thereof is the drain).

In some examples, forming the first semiconductor structure further includes: forming a second doped layer at another end opposite to the upper surface of the semiconductor body; and forming a bit line coupled with the second doped layer, where the bit line extends along the first lateral direction. Here, the bit line is coupled to the drain of the semiconductor body.

In some examples, forming the first semiconductor structure further includes: forming a plurality of third air gaps located between the adjacent bit lines, where the third air gap extends along the first lateral direction.

In some examples, the first isolation structure includes at least one of a first dielectric layer or a first air gap.

In some examples, the first air gap, the second air gap, and the third air gap communicate with each other.

In the examples of the present disclosure, the first air gap, the second air gap, and the third air gap between the two adjacent bit lines communicate with each other, such that the density of the semiconductor device can be increased, a manufacturing process difficulty and manufacturing cost of the semiconductor device are reduced, and a capacitance coupling effect between the adjacent word lines, and between the adjacent semiconductor bodies and the adjacent bit lines can also be reduced, thereby improving the performance of the semiconductor device, and more facilitating future size miniaturization of the semiconductor device.

In some examples, forming the first semiconductor structure further includes: forming a bit line-out structure coupled to the bit line.

In some examples, forming the first semiconductor structure further includes: forming a second interconnect layer coupled to the bit line leading-out structure and the capacitor contact; and forming a second bonding layer coupled to the second interconnect layer. The second bonding layer may include a plurality of second bonding contacts, and dielectric for electrically isolating the second bonding contacts.

In some examples, the method further includes forming a second semiconductor structure, where the second semiconductor structure includes a peripheral circuit, a first interconnect layer, and a first bonding layer. The first bonding layer may include a plurality of first bonding contacts, and dielectric for electrically isolating the first bonding contacts.

In some examples, the method further includes performing bonding connection on the second semiconductor structure and the first semiconductor structure through the first bonding layer and the second bonding layer.

In the examples of the present disclosure, the contact structure and the semiconductor body can be self-aligned, such that the alignment accuracy of the contact structure and the semiconductor body can be improved, and an alignment difficulty of the contact structure and the semiconductor body is reduced, thereby improving the reliability of the semiconductor device, saving manufacturing time and cost, and improving a process speed and efficiency; and in another aspect, as a material of the contact structure between the semiconductor body and the storage element, the metal semiconductor compound has low resistivity, which may realize a better electric connection between the semiconductor body and the storage element, thereby improving the reliability of the semiconductor device.

In the examples of the present disclosure, since the spacings between the adjacent contact structures along the first lateral direction are the same, e.g., the plurality of contact structures arranged along the first lateral direction are uniformly arranged at equal spacing, the storage elements subsequently formed and uniformly arranged may be right aligned with the contact structures in the vertical direction (e.g., the storage elements may be right formed on the contact structures when they are subsequently formed) without offset alignment, such that a connection window between the contact structure and the storage element is improved.

In the examples of the present disclosure, since a size of the contact structure along the X-axis direction is greater than a size of the semiconductor body along the X-axis direction, the connection window between the contact structure and the storage element is further improved, and the effect of further reducing contact resistance can also be achieved.

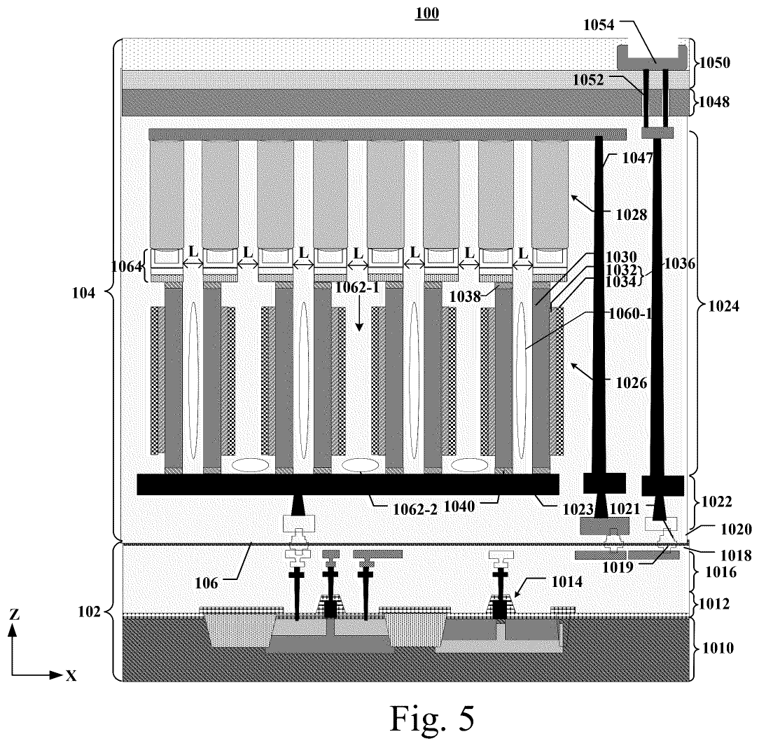

FIG. 5 is a schematic structural diagram II of a semiconductor device provided by an example of the present disclosure. As shown in FIG. 5, the semiconductor device 100 includes a first semiconductor structure 104, where the first semiconductor structure 104 includes: a memory cell array including a plurality of memory cells 1024 arranged in an array along a first lateral direction and a second lateral direction, each memory cell 1024 includes a vertical transistor 1026 and a capacitor structure 1028 coupled to one end of the vertical transistor 1026; and a plurality of contact structures 1064, where the contact structure 1064 is located between the vertical transistor 1026 and the capacitor structure 1028, in two contact structures adjacent to a first contact structure among the plurality of contact structures 1064 along the first lateral direction, distances between any one of the two contact structures and the first contact structure are the same.

As shown in FIG. 5, all of distances between any two adjacent contact structures 1064 among the plurality of contact structures 1064 are L. That is, the plurality of contact structures 1064 arranged along the first lateral direction (X-axis direction) are uniformly arranged at equal spacing.

In some examples, the vertical transistor 1026 includes: a semiconductor body 1030 extending along a vertical direction, and a gate structure 1036 in contact with at least a portion of a side surface of the semiconductor body 1030, where the gate structure 1036 extends along the second lateral direction, and a distance between the adjacent semiconductor bodies 1030 is greater than or equal to a distance between the adjacent contact structures 1064.

In some examples, sidewalls of the contact structure 1064 and semiconductor body 1030 along the first lateral direction are aligned in a vertical direction, and a distance between the other sidewalls of the adjacent semiconductor bodies 1030 along the first lateral direction is greater than a distance between the other sidewalls of the adjacent contact structures 1064 along the first lateral direction.

In some examples, a size of the contact structure 1064 along the first lateral direction is greater than a size of the semiconductor body 1030 along the first lateral direction.

In some examples, the first semiconductor structure 104 further includes: a plurality of bit lines 1023, where the bit line 1023 extends along the first lateral direction and is coupled to the other end of the vertical transistor 1026; and a plurality of isolation structures, where the isolation structure is located between adjacent vertical transistor groups along the second lateral direction and extends the second lateral direction.

In some examples, the plurality of isolation structures include: first isolation structures and second isolation structures alternately arranged along the first lateral direction, where the first isolation structure includes at least one of a first dielectric layer 1062-1 or a first air gap 1062-2, and the second isolation structure includes a second air gap 1060-1.

In some examples, each of a plurality of third air gaps is located between the adjacent bit lines and extends along the first lateral direction.

In some examples, the first air gap 1062-2, the second air gap 1060-1, and the third air gap communicate with each other.

In some examples, the gate structure 1036 includes a gate electrode 1034 and a gate dielectric 1032 between the gate electrode 1034 and the semiconductor body 1030 in the first lateral direction and the second lateral direction.

In some examples, the vertical transistor 1026 further includes a source 1038 and a drain 1040 respectively disposed on two ends of the semiconductor body 1030 in the vertical direction, one of the source 1038 and the drain 1040 of the vertical transistor 1026 is coupled to the capacitor structure 1028 in a respective memory cell, and the other one of the source 1038 and the drain 1040 of the vertical transistor 1026 is coupled to a respective bit line 1023. In some implementations, the source 1038 is coupled to the capacitor structure 1028, and the drain 1040 is coupled to the bit line 1023.

In some examples, the contact structure includes a first conductive layer and a second conductive layer, where the first conductive layer includes a metal semiconductor compound, and the second conductive layer includes a metal. The second conductive layer includes a first sub-layer and a second sub-layer, where the first sub-layer encloses other surfaces of the second sub-layer other than an upper surface. The first sub-layer is in contact with the first conductive layer.

In some examples, the contact structure further includes a first doped layer, where the first doped layer is located on a side of the first conductive layer that is away from the second conductive layer. The first doped layer in the contact structure is in contact with the vertical transistor 1026, and the second sub-layer in the contact structure is in contact with the capacitor structure 1028.

In some examples, the vertical transistor 1026 includes at least one of a gate-all-around (GAA) transistor, a tri-gate transistor, a double-gate transistor, or a single-gate transistor.

In some examples, the capacitor structure 1028 includes at least one of a capacitor, a ferroelectric capacitor, or a phase change memory (PCM) element.

In some examples, the capacitor structure 1028 is a capacitor including a first electrode, a second electrode, and a capacitor dielectric.

In some examples, the semiconductor device 100 further includes a second semiconductor structure 102, where the first semiconductor structure 104 is stacked with the second semiconductor structure 102 along the vertical direction, and the second semiconductor structure 102 includes a peripheral circuit 1012.

An example of the present disclosure further provide a memory system, including: a semiconductor device including a first semiconductor structure, where the first semiconductor structure includes: a memory cell array including a plurality of memory cells arranged in an array along a first lateral direction and a second lateral direction, the memory cell includes a vertical transistor and a storage element coupled to one end of the vertical transistor; a plurality of contact structures, where the contact structure is located between the vertical transistor and the storage element, in two contact structures adjacent to a first contact structure among the plurality of contact structures along the first lateral direction, distances between any one of the two contact structures and the first contact structure are the same; and a memory controller configured to control the semiconductor device.

In some examples, the vertical transistor includes: a semiconductor body extending along a vertical direction, and a gate structure in contact with at least a portion of a side surface of the semiconductor body, where the gate structure extends along the second lateral direction, and a distance between the adjacent semiconductor bodies is greater than or equal to a distance between the adjacent contact structures.

In some examples, sidewalls of the contact structure and semiconductor body along the first lateral direction are aligned in a vertical direction, and a distance between the other sidewalls of the adjacent semiconductor bodies along the first lateral direction is greater than a distance between the other sidewalls of the adjacent contact structures along the first lateral direction.

In some examples, a size of the contact structure along the first lateral direction is greater than a size of the semiconductor body along the first lateral direction.

It is to be noted that the technical solutions set forth in the examples of the present disclosure may be combined arbitrarily in the case of no conflicts.

It is to be understood that references to “one example” or “an example” throughout this specification mean that particular features, structures, or characteristics related to the example are included in at least one example of the present disclosure. Therefore, “in one example” or “in an example” appearing at any place of the whole specification does not necessarily refer to the same example. Furthermore, these particular features, structures, or characteristics may be incorporated in one or more examples in any suitable manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are only for description, and do not represent goodness and badness of the examples.

The above descriptions are merely preferred implementations of the present disclosure, and not intended to limit the patent scope of the present disclosure. Equivalent structure transformation made by utilizing the contents of the specification and the drawings of the present disclosure under the inventive concept of the present disclosure, or direct/indirect application to other related technical fields are both encompassed within the patent protection scope of the present disclosure.

What is claimed is:

1. A semiconductor device, comprising:
a first semiconductor structure, wherein the first semiconductor structure comprises:
a memory cell array comprising a plurality of memory cells arranged in an array along a first lateral direction and a second lateral direction, wherein each memory cell comprises a vertical transistor and a storage element coupled to one end of the vertical transistor; and
a plurality of contact structures, wherein the contact structure is located between the vertical transistor and the storage element,
wherein in two contact structures adjacent to a first contact structure among the plurality of contact structures along the first lateral direction, distances between any one of the two contact structures and the first contact structure are the same.

2. The semiconductor device of claim 1, wherein
the vertical transistor comprises: a semiconductor body extending along a vertical direction, and a gate structure in contact with at least a portion of a side surface of the semiconductor body, wherein the gate structure extends along the second lateral direction; and
a distance between adjacent semiconductor bodies is greater than or equal to a distance between the adjacent contact structures.

3. The semiconductor device of claim 2, wherein sidewalls of the contact structure and the semiconductor body along the first lateral direction are aligned in the vertical direction, and a distance between the other sidewalls of the adjacent semiconductor bodies along the first lateral direction is greater than a distance between the other sidewalls of the adjacent contact structures along the first lateral direction.

4. The semiconductor device of claim 2, wherein a size of the contact structure along the first lateral direction is greater than a size of the semiconductor body along the first lateral direction.

5. The semiconductor device of claim 2, wherein the first semiconductor structure further comprises:
a plurality of bit lines, wherein the bit line extends along the first lateral direction and is coupled to the other end of the vertical transistor; and
a plurality of isolation structures, wherein the isolation structure is located between adjacent vertical transistor groups along the second lateral direction and extends along the second lateral direction.

6. The semiconductor device of claim 5, wherein the plurality of isolation structures comprise:
first isolation structures and second isolation structures alternately arranged along the first lateral direction, wherein the first isolation structure comprises at least one of a first dielectric layer or a first air gap, and the second isolation structure comprises a second air gap.

7. The semiconductor device of claim 6, further comprising:
a plurality of third air gaps, wherein the third air gap is located between adjacent bit lines and extends along the first lateral direction.

8. The semiconductor device of claim 7, wherein the first air gap, the second air gap, and the third air gap communicate with each other.

9. The semiconductor device of claim 2, wherein the gate structure comprises a gate electrode and a gate dielectric between the gate electrode and the semiconductor body in the first lateral direction and the second lateral direction.

10. The semiconductor device of claim 2, wherein the vertical transistor further comprises a source and a drain respectively disposed on two ends of the semiconductor body in the vertical direction, wherein one of the source and the drain of the vertical transistor is coupled to the storage element in a respective memory cell, and the other one of the source and the drain of the vertical transistor is coupled to a respective bit line.

11. The semiconductor device of claim 1, further comprising a second semiconductor structure, wherein the first semiconductor structure is stacked with the second semiconductor structure along a vertical direction, and the second semiconductor structure comprises a peripheral circuit,
wherein the first semiconductor structure and the second semiconductor structure are formed on a same substrate; or
wherein the first semiconductor structure and the second semiconductor structure are formed on different substrates.

12. A method of manufacturing a semiconductor device, comprising:
forming a first semiconductor structure, wherein forming the first semiconductor structure comprises:
forming a memory cell array, wherein the memory cell array comprises a plurality of memory cells arranged in an array along a first lateral direction and a second lateral direction, each memory cell comprises a vertical transistor and a storage element coupled to one end of the vertical transistor; and
forming a plurality of contact structures, wherein the contact structure is located between the vertical transistor and the storage element, and in two contact structures adjacent to a first contact structure among the plurality of contact structures along the first lateral direction, distances between any one of the two contact structures and the first contact structure are the same.

13. The method of claim 12, wherein the forming the first semiconductor structure comprises:
etching a semiconductor substrate through a mask stacking layer to form a semiconductor pillar array, wherein the semiconductor pillar array comprises semiconductor pillar rows arranged along the second lateral direction, and the semiconductor pillar rows are separated by first spacing trenches, and wherein the mask stacking layer comprises a first mask layer and a second mask layer; and
etching the semiconductor pillars through openings formed after removing the first mask layer to form a plurality of second spacing trenches extending along the second lateral direction, wherein the plurality of second spacing trenches separate each semiconductor pillar in the corresponding semiconductor pillar row into two semiconductor bodies.

14. The method of claim 13, wherein the forming the plurality of contact structures comprises:
recessing the second mask layer such that the recessed second mask layers are arranged at equal spacing along the first lateral direction;
removing the recessed second mask layers to form first contact holes;
enlarging the first contact holes to form second contact holes, wherein the second contact hole exposes at least an entire upper surface of the semiconductor body; and
forming the contact structures in the second contact holes.

15. The method of claim 14, wherein the etching the semiconductor pillars through the openings formed after removing the first mask layer comprises:
pulling back the first mask layer along the first spacing trench such that an opening of the first spacing trench that is located in the first mask layer is enlarged;
performing a deposition to form a first sacrificial layer filling the first spacing trench; and
removing the first mask layer to form an opening in the first sacrificial layer, and etching the semiconductor pillar through the opening.

16. The method of claim 15, wherein before removing the recessed second mask layers to form the first contact holes, the forming the first semiconductor structure further comprises:
forming a second sacrificial layer and a second dielectric layer in the second spacing trench,
wherein the forming the first semiconductor structure further comprises:
removing the first sacrificial layer to form a third spacing trench;
forming a word line structure in the third spacing trench;
forming a second trench in the word line structure; and
forming a first isolation structure in the second trench, wherein the word line structure is divided into two word lines through the first isolation structure.

17. The method of claim 14, wherein the forming the memory cell array comprises:
forming a capacitor coupled to the contact structure, wherein the capacitor is coupled to the semiconductor body through the contact structure.

18. The method of claim 17, wherein the forming the first semiconductor structure further comprises:
forming a second doped layer at another end opposite to the upper surface of the semiconductor body; and
forming a bit line coupled with the second doped layer, wherein the bit line extends along the first lateral direction.

19. A memory system, comprising:
a semiconductor device comprising a first semiconductor structure, wherein the first semiconductor structure comprises:
a memory cell array comprising a plurality of memory cells arranged in an array along a first lateral direction and a second lateral direction, wherein a memory cell comprises a vertical transistor and a storage element coupled to one end of the vertical transistor; and
a plurality of contact structures, wherein the contact structure is located between the vertical transistor and the storage element, wherein in two contact structures adjacent to a first contact structure among the plurality of contact structures along the first lateral direction, distances between any one of the two contact structures and the first contact structure is the same; and
a memory controller configured to control the semiconductor device.

20. The memory system of claim 19, wherein
the vertical transistor comprises a semiconductor body extending along a vertical direction, and a gate structure in contact with at least a portion of a side surface of the semiconductor body, wherein the gate structure extends along the second lateral direction;
a distance between adjacent semiconductor bodies is greater than or equal to a distance between the adjacent contact structures;
sidewalls of the contact structure and a semiconductor body along the first lateral direction are aligned in a vertical direction, and a distance between the other sidewalls of adjacent semiconductor bodies along the first lateral direction is greater than a distance between the other sidewalls of the adjacent contact structures along the first lateral direction; and
a size of the contact structure along the first lateral direction is greater than a size of the semiconductor body along the first lateral direction.
